(19) United States
(12) Patent Application Publication
(10) Pub. No.: US 2020/0236784 A1
(43) Pub. Date: Jul. 23, 2020

(54) DISPLAY APPARATUS

(71) Applicant: SHARP KABUSHIKI KAISHA, Osaka (JP)

(72) Inventors: SEIJI MURAOKA, Osaka (JP); RYOSUKE YAGI, Osaka (JP); SHIGENORI MORIOKA, Osaka (JP)

(21) Appl. No.: 16/741,177

(22) Filed: Jan. 13, 2020

(30) Foreign Application Priority Data
Jan. 17, 2019 (JP) 2019-006282

(51) Int. Cl. H05K 1/11; H05K 1/18

(52) U.S. Cl. CPC H05K 1/112; H05K 1/181; H05K 2201/09227; H05K 2201/09609; H05K 2201/10128

(57) ABSTRACT

A display apparatus has a wiring board connected to a first connection portion at an outer edge of a display. The number of first wires on a first surface of the wiring board is less than the number of second wires on a second surface. Through-holes adjacent to each other are disposed at positions that differ in the extending direction of the first wires.

### BACKGROUND

### 1. Field

The present disclosure relates to a display apparatus.

### 2. Description of the Related Art

Currently, display apparatuses are used extensively in products ranging from mobile devices such as smartphones to consumer electronics such as television sets. Display apparatuses are requested to display high-quality images. Accordingly, the number of wires connected to the display panel of such a display apparatus is increased, and the wires may be connected with a small pitch. In addition, a display apparatus generally has a picture-frame portion not used to display images. The width of the picture-frame portion of a display apparatus is desirably reduced from the viewpoint of design or the like.

Regarding connection of wires with a small pitch, there is a known technique in which the lengths and widths of terminals in the first and the second columns are different from each other so that a short-circuit does not occur between the terminals arranged in a plurality of rows (see, for example, Japanese Unexamined Patent Application Publication No. 2008-287271 filed on Nov. 27, 2008). Regarding reducing the width of the picture-frame portion, there is a known technique for superposing the wires extended from free space provided in a driver IC and the wires extended from the display panel on each other when the driver IC having the free space is mounted in a display panel (see, for example, Japanese Unexamined Patent Application Publication No. 2014-157219 filed on Aug. 28, 2014).

However, the related art described above has room for consideration in terms of the connection of wires with a small pitch and in terms of reducing the width of the picture-frame portion.

It is desirable to achieve a display apparatus in which wires are connected with a small pitch and in which the width of the picture-frame portion is reduced.

### SUMMARY

A display apparatus according to an aspect of the present disclosure includes a display that displays an image, a first connection portion disposed at an outer edge of the display, and a wiring board connected to the first connection portion. The wiring board includes a first surface, a second surface opposite to the first surface, a through-hole region located at an end portion of the wiring board, the through-hole region having a plurality of through-holes, a second connection portion disposed on an inner side of the through-hole region in a planar direction of the second surface, the second connection portion being connected to the first connection portion, a plurality of first wires disposed to correspond to the through-holes, the first wires extending to the through-hole region on the first surface, passing through the through-holes, and extending to the second connection portion on the second surface, and a plurality of second wires extending to the second connection portion on the second surface. The number of the first wires is less than the number of the second wires. At least the through-holes corresponding to the first wires adjacent to each other are disposed at positions that differ in an extending direction of the first wires on the first surface.

### BRIEF DESCRIPTION OF THE DRAWINGS

FIG. 1 schematically illustrates the structure of a major part of a display apparatus according to Embodiment 1 of the present disclosure;

FIG. 2 schematically illustrates a cross section of the display apparatus illustrated in FIG. 1 taken along line II-II;

FIG. 3 schematically illustrates the structure of a major part of a display apparatus used for comparison;

FIG. 4A schematically illustrates the structure of an end portion of a wiring board in the display apparatus used for comparison, and FIG. 4B schematically illustrates the structure of an end portion of a wiring board in the display apparatus according to Embodiment 1;

FIG. 5A schematically illustrates the positional relationship between wires and through-holes in the end portion of the wiring board in the display apparatus used for comparison, and FIG. 5B schematically illustrates the positional relationship between wires and the through-holes in the end portion of the wiring board in the display apparatus according to Embodiment 1;

FIG. 6 schematically illustrates the structure of a major part of a display apparatus according to Embodiment 2 of the present disclosure; and

FIG. 7 schematically illustrates the structure of a major part of a display apparatus according to Embodiment 3 of the present disclosure;

### DESCRIPTION OF THE EMBODIMENTS

### Embodiment 1

### (Overall Structure)

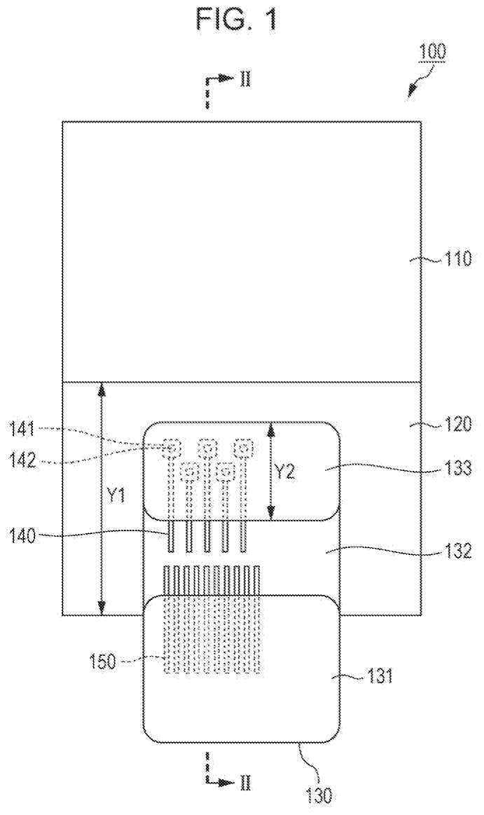

An embodiment of the present disclosure will be described in detail below. The embodiment relates to the structure of a connection portion of a product in which a flexible wiring board is connected to the wiring board of a planar display apparatus. FIG. 1 schematically illustrates the structure of a major part of the display apparatus according to Embodiment 1 of the present disclosure. As illustrated in FIG. 1, a display apparatus 100 includes a display 110 that displays an image, a first connection portion 120 disposed at an outer edge of the display 110, and a wiring board 130 connected to the first connection portion 120.

The display 110 is a planar device that displays an image and is, for example, a liquid crystal display panel, a plasma display, or an organic EL panel. The display 110 is a full high-definition display in terms of displaying high-definition images. The display 110 has 1920 pixels in the lateral direction and 1080 pixels in the longitudinal direction. The display 110 described above is also referred to as “full high-definition (HD)” or a “full HD device”.

The first connection portion 120 is a portion for electrically connecting to the wires of the wiring board. Although the first connection portion 120 is disposed at an outer edge of the display 110, the first connection portion 120 may be peripherally disposed or may not be peripherally disposed. Connection terminals in accordance with the structure of, for example, the display 110 are disposed on the surface of the first connection portion 120. When the pixels of the display 110 include, for example, red (R), green (G), and blue (B) subpixels, a number of connection terminals equal to at least three times 1080 (pixels) are disposed in the portion, extending from the short side of the display 110, of the first connection portion 120.

The first connection portion 120 is electrically connected to the wiring board 130 by a known technique. For example, the first connection portion 120 is electrically connected to the wiring board 130 via an anisotropic conductive film (ACF) 160. The ACF 160 electrically connects the plurality of connection terminals of the first connection portion 120 to a plurality of first wires 140 and a plurality of second wires 150 disposed in a second connection portion 132 of the wiring board 130, which will be described later, and adheres the wiring board 130 to the first connection portion 120.

### (Structure of the Wiring Board)

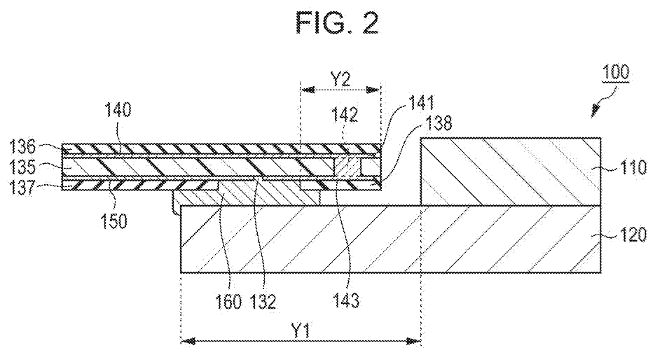

FIG. 2 schematically illustrates a cross section of the display apparatus 100 taken along line II-II in FIG. 1. The wiring board 130 is flexible. The wiring board 130 is, for example, a chip on film (COF). The wiring board 130 has a first surface that is one surface and a second surface that is on the opposite side (back surface) of the one surface. In the stacking direction, the wiring board 130 includes a flexible sheet 135 made of polyimide, the plurality of first wires 140 on one surface thereof, the plurality of second wires 150 on the other surface thereof, an insulating film 136 that covers the first wires 140, and insulating films 137 and 138 that cover the second wires 150. However, part or all of these insulating films may be omitted insofar as product reliability is substantially ensured. Both the first wires 140 and the second wires 150 are made of an electrically conductive material, such as copper foil.

In addition, the wiring board 130 includes a board body 131, the second connection portion 132 near the end portion of the board body 131, and a through-hole region 133 near the end portion of the second connection portion 132 in a planar direction of the wiring board 130. The board body 131 is the portion in which, for example, the insulating film 136 on the first surface is superposed on the insulating film 137 on the second surface in the stacking direction. The through-hole region 133 is located at the end portion of the wiring board 130 and has a plurality of through-holes 142. The through-hole region 133 is the portion that is superposed on, for example, the insulating film 138 on the second surface in the end portion of the wiring board 130 in the stacking direction. The second connection portion 132 is disposed on an inner side of the through-hole region in the planar direction of the second surface. The second connection portion 132 is the portion in which, for example, neither the insulating film 137 nor the insulating film 138 on the second surface is disposed in the stacking direction.

The first wires 140 are disposed so as to correspond respectively to the through-holes 142. That is, substantially the same number of the first wires 140 as the through-holes 142 are disposed, and the first wires 140 correspond to the through-holes 142 on a substantially one-to-one basis. The first wires 140 extend from the board body 131 to the through-holes 142 on the first surface. Border portions 141 of the through-holes 142 are formed around the through-holes 142 of the first wires 140. Each border portion 141 may have any planar shape insofar as the border portion 141 surrounds the through-hole 142 and the shape is, for example, substantially square.

The first wires 140 extend to the second connection portion 132 on the second surface. For example, the first wire 140 has a border portion 143 of the through-hole 142 on the second surface, and the first wire 140 extends from the border portion 143 to the second connection portion 132. The through-hole 142 accommodates an electrically conductive material. As described above, the first wires 140 extend to the through-hole region 133 on the first surface, pass through the through-holes 142, and extend to the second connection portion 132 on the second surface.

The second wires 150 extend from the board body 131 to the second connection portion 132 on the second surface of the wiring board 130. Both the first wires 140 and the second wires 150 are covered with any of the insulating films 136 to 138 in the portion other than the second connection portion 132 of the wiring board 130 and exposed to the second surface of the wiring board 130 in the second connection portion 132.

As described above, the flexible wiring board 130 is connected to the first connection portion 120 via the ACF 160 in the display apparatus 100. In the wiring board 130, the wires are disposed on two layers: the front and back layers. The first wires 140 on the front surface (first surface) are connected, via the through-holes 142, to the second connection portion 132 by the wires on the back surface (second surface) in an electrically conductive manner.

In the display apparatus 100, the number of the first wires 140 is less than the number of the second wires 150. For example, the number of the first wires 140 is half the number of the second wires 150.

In addition, in the display apparatus 100, at least the through-holes 142 corresponding to the first wires 140 adjacent to each other are disposed at positions that differ in the extending direction of the first wires 140 on the first surface. More specifically, the through-holes 142 are arranged alternately in two rows with respect to the extending direction. Such disposition is also referred to as a staggered arrangement.

Since the border portion 141 is formed around the through-hole 142, a certain area wider than the first wire 140 is provided. Accordingly, when the first wires 140 are disposed with a small pitch, the through-holes 142 are disposed at positions that differ in the extending direction (direction indicated by arrow Y in the drawings) of the first wires 140. Normally, the positions of the through-holes 142 are aligned in the extending direction at appropriate intervals. Accordingly, the through-holes 142 are disposed in a plurality of rows with respect to the extending direction.

### (Description of the Operation and Effect)

In the display apparatus 100, the number of the first wires 140 connected to the through-holes 142 is less than the number of the second wires 150 not connected to the through-holes 142. Since this reduces the number of the through-holes 142, the number of rows of the through-holes 142 can be reduced. As a result, the size in the Y-direction of the first connection portion 120 can be reduced, thereby further reducing the width of the picture-frame portion of the display apparatus 100.

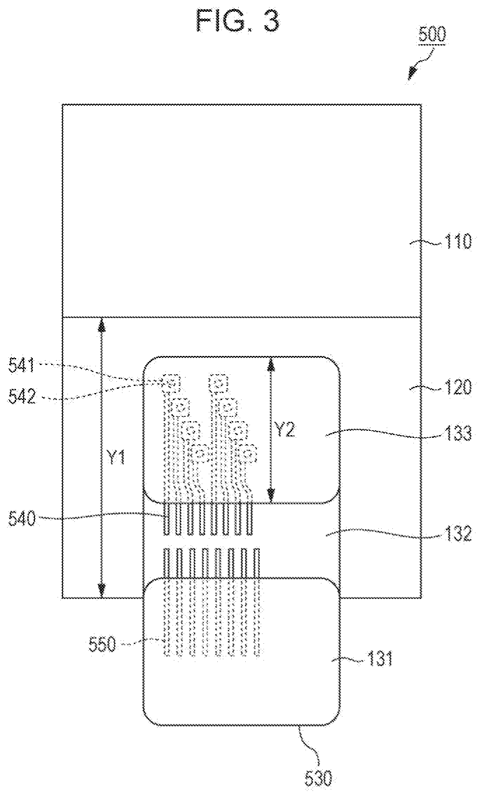

The above advantage of the display apparatus 100 will be described below by comparing the display apparatus 100 with a display apparatus used for comparison in which the same number of the first wires and the second wires are disposed. FIG. 3 schematically illustrates the structure of a major part of the display apparatus used for comparison.

### (Structure of the Display Apparatus Used for Comparison)

As illustrated in FIG. 3, a display apparatus 500 used for comparison has the same structure as the display apparatus 100 with the exception of a wiring board 530. The wiring board 530 has the same structure as the wiring board 130 of the display apparatus 100 except that the number of the first wires and the number of the second wires are different and the number of rows of the through-holes is larger.

In the wiring board 530, the number of first wires 540 is the same as the number of second wires 550. In the wiring board 530, through-holes 542 are staggered in four rows instead of two rows.

As described above, although the number of the first wires 140 is half the number of the second wires 150 (the ratio of the number of the first wires 140 to the number of the second wires 150 is 1/2) in the display apparatus 100 according to the embodiment, the total number of the first wires and the second wires of the display apparatus 100 is the same as that of the display apparatus 500. That is, the reduction in the number of the first wires of the display apparatus 100 relative to the number of the first wires of the display apparatus 500 is the same as the increase in the number of the second wires of the display apparatus 100 relative to the number of the second wires of the display apparatus 500.

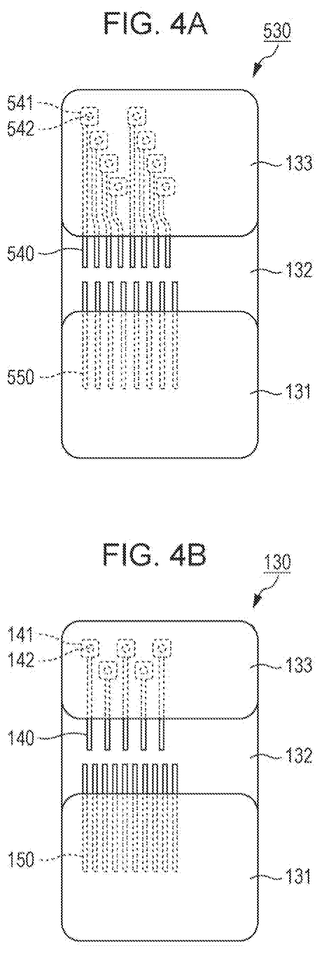

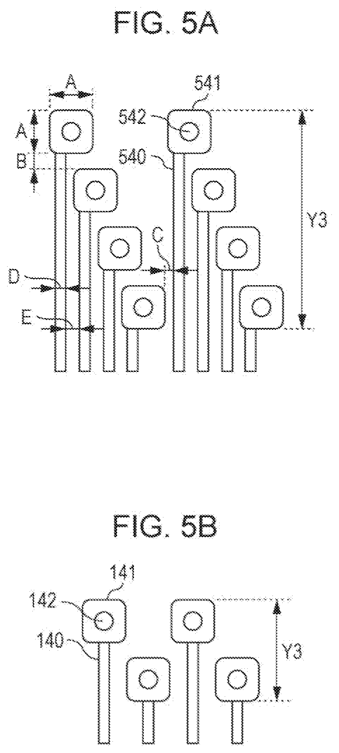

Since the display apparatus 500 used for comparison has the same number of the first wires and the second wires, the first wires have larger areas for the through-holes. As a result, reducing the width of the picture-frame portion is difficult in the display apparatus 500. A more detailed description will be given below with reference to the drawings. FIG. 4A schematically illustrates the structure of an end portion of the wiring board in the display apparatus used for comparison. FIG. 5A schematically illustrates the positional relationship between the wires and the through-holes at the end portion of the wiring board in the display apparatus used for comparison.

Arrow Y1 in the drawings represents the length of the first connection portion 120 in the Y-direction (extending direction of the first wires). Y2 represents the length of the through-hole region in the Y-direction. Y3 represents the installation length of the through-holes in the Y-direction formed in the through-hole region. Y3 also represents the length, in the Y-direction, of rows of the through-holes disposed in rows.

### (Specific Description of the Structure of the Major Part of the Display Apparatus Used for Comparison)

It is assumed that 3290 connection terminals are present in the lateral direction in the first connection portion 120 of the display apparatuses 100 and 500. Of these connection terminals, 3240 (1080×3) connection terminals correspond to RGB colors of 1080 dots in the lateral direction and 50 connection terminals correspond to wires for gate driving. It is assumed that the number of the first wires and the second wires on the wiring board are also the same as the number of the connection terminals.

In the display apparatus 500, the number of the first wires 540 is the same as the number of the second wires 550 on the wiring board 530. Accordingly, the number of first wires 540 is 1645 (3290/2) and the number of the second wires 550 is 1645 (3290/2) in the display apparatus 500.

As described above, the wiring board is a COF and the width thereof is determined by the standard. The wiring board 530 has a maximum width of approximately 63 mm. Accordingly, the maximum pitch of the first wires 540 and the second wires 550 is 38.3 μm (63 mm/1645 wires=0.0383 mm).

On the other hand, regarding the through-holes, the minimum pitches of the through-holes and the first wires are determined by design rules thereof. An example of the design rules is shown in Table 1. In addition, Table 2 shows the numbers of rows of the through-holes in accordance with the rules under the above conditions and the minimum pitch of the first wires for the individual rows.

TABLE 1
Pattern design rules

| | | DIMENSION |
|---|---|---|
| | ITEM | (μm) |
| A | SIZE OF THROUGH-HOLE | 75 |
| B | SPACE BETWEEN THROUGH-HOLES | 15 |
| C | SPACE BETWEEN THROUGH-HOLE | 12 |
| | AND FIRST WIRE | |
| D | WIDTH OF FIRST WIRE | 10 |
| E | SPACE BETWEEN FIRST WIRES | 12 |

TABLE 2
Number of rows of through-holes and minimum pitch of wires

| NUMBER OF ROWS OF | MINIMUM PITCH OF |
|---|---|
| THROUGH-HOLES (—) | FIRST WIRES (μm) |
| 1 | 87.0 |
| 2 | 54.5 |
| 3 | 43.7 |
| 4 | 38.3 |
| 5 | 35.0 |

As illustrated in FIG. 5A, “A” in Table 1 is the size of a through-hole and represents the dimension of the border portion. “B” is the size of the space between through-holes and represents the length in the Y-direction of the clearance between the through-holes. “C” is the size of the space between a through-hole and a first wire and represents the length of the clearance between the through-hole and the first wire in the direction in which the first wires are adjacent to each other. “D” represents the width of a first wire. “E” is the space between adjacent first wires and represents the size of the clearance between adjacent first wires.

Accordingly, in the display apparatus 500, the number of rows of the through-holes is four or more and the minimum value of the length Y3 in this case is 345 μm.

### Specific Description of the Structure of the Major Part of the Display Apparatus According to the Embodiment

As described above, wires are disposed in the display apparatus 100 according to the embodiment so that the number of the first wires is half the number of the second wires. Accordingly, the first wires in the display apparatus 100 have a larger pitch and fewer rows (two rows) of the through-holes than in the display apparatus 500. Therefore, in the display apparatus 100, the dimension Y3 is smaller and the dimension Y2 can be smaller, and accordingly, the dimension Y1 can be smaller than in the display apparatus 500. Since the dimension Y1 of the first connection portion 120 of the display apparatus 100 can be smaller than in the display apparatus 500 as described above, the width of the picture-frame portion around the display 110 can be reduced. A more detailed description will be given below with reference to the drawings.

FIG. 4B schematically illustrates the structure of the end portion of the wiring board in the display apparatus according to Embodiment 1. FIG. 5B schematically illustrates the positional relationship between the wires and the through-holes at the end portion of the wiring board in the display apparatus according to Embodiment 1.

As described above, the number of the first wires 140 is half (½) the number of the second wires 150 in the display apparatus 100. That is, the number of the first wires 140 is 1097 and the number of the second wires 150 is 2193. Accordingly, in the display apparatus 100, the pitch of the first wires 140 is 57.4 μm (63 mm/1097 wires=0.0574 mm). As shown in Table 2, the number of rows of the through-holes can be two, and the minimum value of the length Y3 in this case is 165 μm. Accordingly, in the display apparatus 100, the dimension Y3 of rows of the through-holes can be 180 μm smaller than in the display apparatus 500. The pitch of the second wires 150 in this case is 28.7 μm (63 mm/2193 wires=0.0287 mm). This pitch is large enough for the second wires 150 to be arranged.

As clarified in the above description, in the display apparatus 100 according to the embodiment, the dimension Y2 of the through-hole region in the Y-direction can be smaller than in the display apparatus 500 having the same number of the first wires and the second wires. Therefore, the dimension Y1 of the first connection portion 120 in the Y-direction of the display apparatus 100 can be smaller. Accordingly, in the display apparatus 100, the width of the picture-frame portion around the display 110 can be reduced more than in the display apparatus 500 within the range in which the dimension Y3 can be smaller.

### Embodiment 2

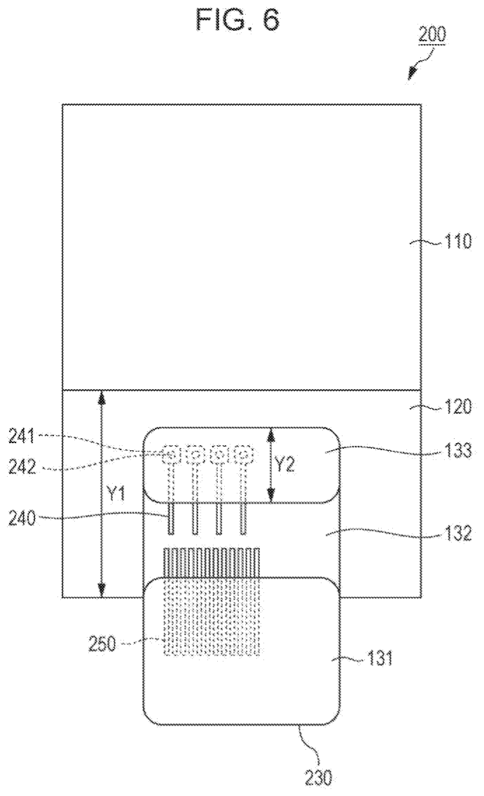

Another embodiment of the present disclosure will be described below. For convenience of description, components having the same functions as those described in the above embodiment are denoted by the same reference characters, and descriptions thereof are omitted. In the embodiment, shapes and dimensions in the structure of the above embodiment may be adjusted as appropriate within an achievable range. FIG. 6 schematically illustrates the structure of a major part of a display apparatus according to Embodiment 2 of the present disclosure.

As illustrated in FIG. 6, a display apparatus 200 according to the embodiment has the same structure as the display apparatus 100 described above except that the display apparatus 200 has a wiring board 230 instead of the wiring board 130. The wiring board 230 has the same structure as the wiring board 130 of the display apparatus 100 described above except that the number of first wires 240 is one-third (⅓) the number of second wires 250 and the number of rows of the through-holes 242 is one.

Since the number of rows of the through-holes is one in the display apparatus 200, the dimension Y3 can be smaller than in the display apparatus 500 and the dimension Y1 of the first connection portion 120 in the Y-direction can thereby be smaller. Accordingly, in the display apparatus 200, the picture-frame portion around the display 110 can be narrower than in the display apparatus 500 within the range in which the dimension Y3 can be smaller.

In contrast, the pitch of second wires 250 is narrower in the display apparatus 200. Accordingly, in the display apparatus 200, various design matters such as the width and pitch of the second wire 250 and the number of connection terminals in the first connection portion 120 may be considered as appropriate.

### Embodiment 3

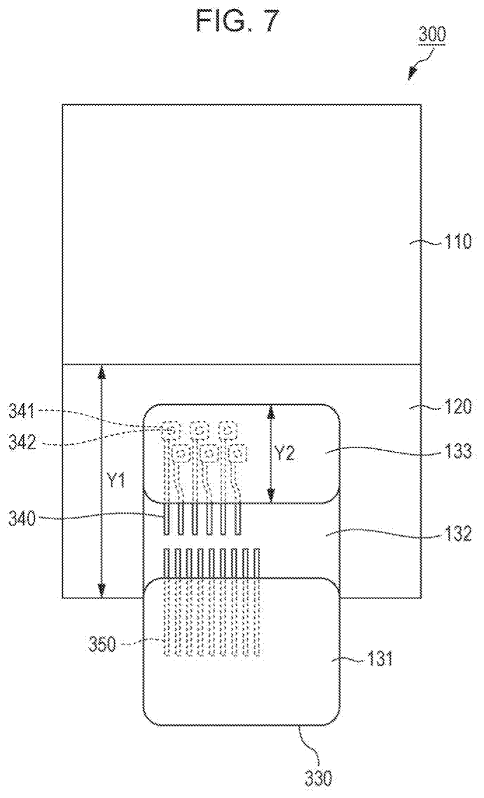

Another embodiment of the present disclosure will be described below. For convenience of description, components having the same functions as those described in the above embodiments are denoted by the same reference characters, and descriptions thereof are omitted. In the embodiment, shapes and dimensions in the structures of the above embodiments may be adjusted as appropriate within an achievable range. FIG. 7 schematically illustrates the structure of a major part of a display apparatus according to Embodiment 3 of the present disclosure.

As illustrated in FIG. 7, a display apparatus 300 according to the embodiment has the same structure as the display apparatus 100 described above except that the display apparatus 300 has a wiring board 330 instead of the wiring board 130. The wiring board 330 has the same structure as the wiring board 130 of the display apparatus 100 except that the number of first wires 340 is two-thirds (⅔) the number of second wire 350. The number of rows of through-holes 342 in the wiring board 330 is two as in the wiring board 130.

The number of the first wires 340 of the display apparatus 300 is more than that of the display apparatus 100. Accordingly, the display apparatus 300 has the same effects as the display apparatus 100 and is useful when it is difficult to greatly reduce the number of the first wires 340.

### [Modifications]

Although the total number of the first wires and the second wires is the same as the number of the connection terminals in the first connection portion in the above embodiments for the purpose of clear description, the total number of the wires may differ from the number of the connection terminals insofar as the effects of the embodiments are obtained. For example, some of the wires of the wiring board or the connection terminals of the display may be or may not be used for connection.

In addition, with respect to the display apparatus 500, the reduction in the number of the first wires is the same as the increase in the number of the second wires to make the contrast with the display apparatus 500 clear in the above embodiments. However, the reduction may differ from the increase insofar as the effects of the embodiments are obtained. For example, the first wires or the second wires may be provided additionally.

In addition, the through-holes are disposed in a plurality of rows in a staggered arrangement regularly in the above embodiments. Although such regular disposition is useful in terms of, for example, the improvement in productivity of the wiring board, the through-holes may be disposed in a plurality of rows in a form other than the staggered arrangement insofar as the effects of the embodiments are obtained. For example, the through-holes may be disposed in a plurality of rows alternately disposed irregularly in the Y-direction.

In addition, although the display 110 is a full high-definition display in the above embodiments, the display 110 may be a display of different specification insofar as the effects of the embodiments are obtained. The embodiments of the present disclosure are more useful in a form in which a wiring board is connected to a device having closely-arranged connection terminals such as the display 110 of full high-definition. The above embodiments of the present disclosure are also useful in a display device with a display that has a high resolution such as, for example, wide quad high-definition (WQHD), 4K, or 2K and drives two or more of pixels (for example, R, G, and B) of the display for one connection terminal using the low temperature poly silicon (LTPS) technique.

### [Conclusion]

The display apparatus (100, 200, 300) according to a first aspect of the present disclosure includes a display (110) that displays an image, a first connection portion (120) disposed at an outer edge of the display, and a wiring board (130) connected to the first connection portion. The wiring board includes a first surface, a second surface opposite to the first surface, a through-hole region (133) located at an end portion of the wiring board, the through-hole region having a plurality of through-holes (142, 242, 342), a second connection portion (132) disposed on an inner side of the through-hole region in a planar direction of the second surface, the second connection portion being connected to the first connection portion, a plurality of first wires (140, 240, 340) disposed to correspond to the through-holes, the first wires extending to the through-hole region on the first surface, passing through the through-holes, and extending to the second connection portion on the second surface, and a plurality of second wires (150, 250, 350) extending to the second connection portion on the second surface. The number of the first wires is less than the number of the second wires. At least the through-holes corresponding to the first wires adjacent to each other are disposed at positions that differ in the extending direction of the first wires on the first surface.

In the structure described above, the pitch of the first wires is wider, the pitch of the second wires is narrower, and the number of rows of the through-holes can be smaller than in the structure in which substantially the same number of the first wires and the second wires are disposed. Accordingly, the wires can be connected with a small pitch and the picture-frame portion can be narrower in the display apparatus.

In the display apparatus according to a second aspect of the present disclosure, a reduction in the number of the first wires actually disposed relative to the number of the first wires when an identical number of the first wires and the second wires are disposed may be identical to an increase in the number of the second wires actually disposed relative to the number of the second wires when an identical number of the first wires and the second wires are disposed in the first aspect described above.

In the structure described above, the number of rows of the through-holes can be smaller than in the display apparatus having the wiring board on which substantially the same number of the first wires and the second wires are disposed even when one or both of the number of the wires and the number of the connection terminals on the wiring board are the same, thereby reducing the width of the picture-frame portion while achieving an expected electric connection in the related art.

In the display apparatus according to a third aspect of the present disclosure, the through-holes may be disposed in a staggered arrangement in two or more rows with respect to the extending direction of the first wires in the first or second aspect described above.

In the structure described above, the through-holes can be disposed most closely in the direction where the through-holes are adjacent to each other and the through-holes and the first wires can be disposed most closely in the range in which the picture-frame portion is narrower.

In the display apparatus according to a fourth aspect of the present disclosure, the display may have a resolution equal to or higher than full high-definition in any one of the first to third aspects described above.

In the structure described above, the picture-frame portion can be narrower than in the related art in a display apparatus of high-definition.

The present disclosure is not limited to the above embodiments, various changes may be made within the scope of the appended claims, and embodiments obtained by combining technical means disclosed in different embodiments as appropriate are also included in the technical scope of the present disclosure. In addition, new technical features may be formed by combining technical means disclosed in the embodiments.

The present disclosure contains subject matter related to that disclosed in Japanese Priority Patent Application JP 2019-006282 filed in the Japan Patent Office on Jan. 17, 2019, the entire contents of which are hereby incorporated by reference.

What is claimed is:

1. A display apparatus comprising:
a display that displays an image;
a first connection portion disposed at an outer edge of the display; and
a wiring board connected to the first connection portion, wherein
the wiring board includes
a first surface,
a second surface opposite to the first surface,
a through-hole region located at an end portion of the wiring board, the through-hole region having a plurality of through-holes,
a second connection portion disposed on an inner side of the through-hole region in a planar direction of the second surface, the second connection portion being connected to the first connection portion,
a plurality of first wires disposed to correspond to the through-holes, the first wires extending to the through-hole region on the first surface, passing through the through-holes, and extending to the second connection portion on the second surface, and
a plurality of second wires extending to the second connection portion on the second surface, and
the number of the first wires is less than the number of the second wires and
at least the through-holes corresponding to the first wires adjacent to each other are disposed at positions that differ in an extending direction of the first wires on the first surface.

2. The display apparatus according to claim 1, wherein
a reduction in the number of the first wires actually disposed relative to the number of the first wires when an identical number of the first wires and the second wires are disposed is identical to an increase in the number of the second wires actually disposed relative to the number of the second wires when an identical number of the first wires and the second wires are disposed.

3. The display apparatus according to claim 1, wherein
the through-holes are disposed in a staggered arrangement in two or more rows with respect to the extending direction.

4. The display apparatus according to claim 1, wherein
the display has a resolution equal to or higher than full high-definition.
